(19) United States
(12) Patent Application Publication
(10) Pub. No.: US 2009/0093128 A1
(43) Pub. Date: Apr. 9, 2009

(54) METHODS FOR HIGH TEMPERATURE DEPOSITION OF AN AMORPHOUS CARBON LAYER

(76) Inventors: MARTIN JAY SEAMONS, San Jose, CA (US); Yoganand N. Saripalli, Santa Clara, CA (US); Kwangduk Douglas Lee, Santa Clara, CA (US); Bok Hoen Kim, San Jose, CA (US); Visweswaren Sivaramakrishnan, Cupertino, CA (US); Wendy H. Yeh, Mountain View, CA (US); Josephine Ju-Hwei Chang Liu, Boise, ID (US); Amir Al-Bayati, San Jose, CA (US); Derek R. Witty, Fremont, CA (US); Hichem M'Saad, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/868,859

(22) Filed: Oct. 8, 2007

(51) Int. Cl. H01L 21/47

(52) U.S. Cl. 438/778; 257/E21.492

(57) ABSTRACT

Methods for high temperature deposition an amorphous carbon film with improved step coverage are provided. In one embodiment, a method for of depositing an amorphous carbon film includes providing a substrate in a process chamber, heating the substrate at a temperature greater than 500 degrees Celsius, supplying a gas mixture comprising a hydrocarbon compound and an inert gas into the process chamber containing the heated substrate, and depositing an amorphous carbon film on the heated substrate having a stress of between 100 mega-pascal (MPa) tensile and about 100 mega-pascal (MPa) compressive.

### BACKGROUND

1. Field of the Invention

The present invention relates to the fabrication of integrated circuits and to a process for depositing materials on a substrate. More specifically, the invention relates to a high temperature process for depositing carbon materials on a substrate.

2. Description of the Background Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. For example, in process sequences that use conventional photo lithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer. Thus, a highly selective etchant enhances accurate pattern transfer.

As the geometry limits of the structures used to form semiconductor devices are pushed against technology limits, the need for accurate pattern transfer for the manufacture of structures have small critical dimensions and high aspect ratios has become increasingly difficult. For example, the thickness of the energy sensitive resist, such as resist layer for 193 nm, has been reduced in order to control pattern resolution. Such thin resist layers (e.g., less than about 2000 Å) can be insufficient to mask underlying material layers during the pattern transfer step due to attack by the chemical etchant. An intermediate layer (e.g., silicon oxynitride, silicon carbine or carbon film), called a hardmask layer, is often used between the energy sensitive resist layer and the underlying material layers to facilitate pattern transfer because of its greater resistance to chemical etchants. When etching materials to form structures having aspect ratios greater than about 5:1 and/or critical dimensional less than about 50 nm, the hardmask layer utilized to transfer patterns to the materials is exposed to aggressive etchants for a significant period of time. After a long period of exposure to the aggressive etchants, the hardmask layer may be bent, collapsed, toppled, twisted, distorted or deformed, resulting in inaccurate pattern transfer and loss of dimensional control. Additionally, stress in the deposited film and/or hardmask layer the film stack may also result in stress induced line edge bending and/or line breakage.

Furthermore, the similarity of the materials selected for the hardmask layer and the adjacent layers disposed in the film stack may also result in similar etch properties therebetween, thereby resulting in poor selectivity during etching. Poor selectivity between the hardmask layer and adjacent layers may result in non-uniform, tapered and deformed profile of the hardmask layer, thereby leading to poor pattern transfer and failure of accurate structure dimension control.

Therefore, there is a need in the art for an improved method for depositing a hardmask layer.

### SUMMARY

Methods for high temperature deposition an amorphous carbon film with improved step coverage are provided. In one embodiment, a method for of depositing an amorphous carbon film includes providing a substrate in a process chamber, heating the substrate at a temperature greater than 500 degrees Celsius, supplying a gas mixture comprising a hydrocarbon compound and an inert gas into the process chamber containing the heated substrate, and depositing an amorphous carbon film on the heated substrate having a stress of between 100 mega-pascal (MPa) tensile and about 100 mega-pascal (MPa) compressive.

In another embodiment, a method of depositing an amorphous carbon film includes providing a substrate having a film stack in a process chamber, wherein the film stack has no metal layers contained therein, flowing a gas mixture comprising a hydrocarbon compound and an inert gas into the process chamber, the inert gas selected from at least one of helium or argon gas, maintaining the substrate at a temperature between about 550 degrees Celsius and about 750 degrees Celsius, and depositing an amorphous carbon film on the heated substrate, wherein a rate of inert gas flow is selected commensurate with the substrate temperature to produce a stress of between 100 mega-pascal (MPa) tensile and about 100 mega-pascal (MPa) compressive in the deposited film.

In another embodiment, a method of depositing an amorphous carbon film includes providing a substrate having a film stack in a process chamber, wherein the film stack has no metal layers contained therein, flowing a gas mixture into the process chamber, the gas mixture comprising an inert gas and at least one of a propane compound or an acetylene compound, the inert gas selected from at least one of helium or argon gas, maintaining the substrate at a temperature between about 550 degrees Celsius and about 750 degrees Celsius, and depositing an amorphous carbon film on the substrate, wherein the amount of inert gas and the substrate temperature are selected to produce a predefined stress level between about 100 mega-pascal (MPa) tensile and about 100 mega-pascal (MPa) compressive in the deposited amorphous carbon film.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic illustration of an apparatus that can be used for the practice of this invention;

FIG. 2 depicts a flow process diagram of a deposition process according to one embodiment of the present invention; and

FIGS. 3A-3C depict a sequence of schematic cross-sectional views of a substrate structure incorporating an amorphous carbon layer deposited according to the method of FIG. 2.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a method of high temperature forming an amorphous carbon film at high temperatures. In one embodiment, the amorphous carbon film is suitable for use as a hardmask layer. The amorphous carbon film is deposited by decomposing a gas mixture including a hydrocarbon compound and an inert gas at a high process temperature, e.g, greater than about 500 degrees Celsius. The higher process temperature utilized during deposition provides an amorphous carbon film having desired mechanical properties, such as a low film stress while maintaining high density, hardness and elastic modulus, which provides high film selectivity to other material layers for the subsequent etching process. Additionally, the amorphous carbon film deposited at high temperature also provides desired optical film properties, such as desired range of index of refraction (n) and the absorption coefficient (k) advantageous for photolithographic patterning processes.

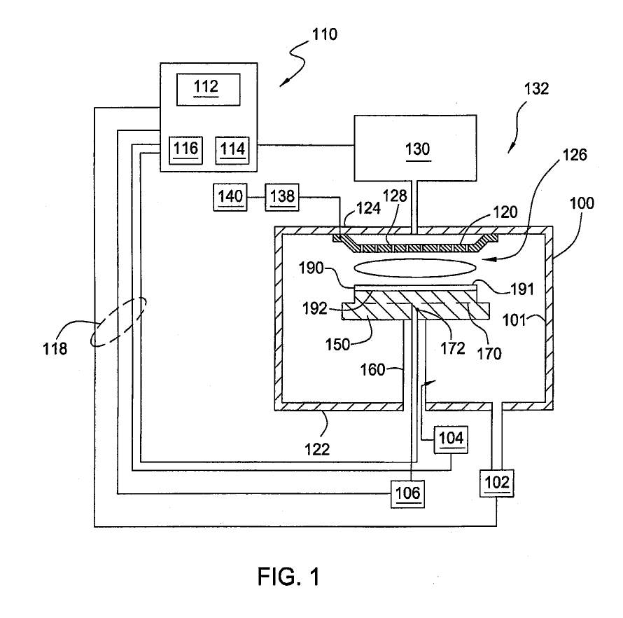

FIG. 1 is a schematic representation of a substrate processing system 132 that can be used to perform amorphous carbon layer deposition in accordance with embodiments of the present invention. Details of one example of a substrate processing system 132 that may be used to practice the invention is described in commonly assigned U.S. Pat. No. 6,364,954 issued on Apr. 2, 2002, to Salvador et. al., and is herein incorporated by reference. Other examples of systems that may be used to practice the invention include CENTURA®, PRECISION 5000® and PRODUCER® deposition systems, all available from Applied Materials Inc., Santa Clara, Calif. It is contemplated that other processing system, including those available from other manufacturers, may be adapted to practice the invention.

The processing system 132 includes a process chamber 100 coupled to a gas panel 130 and a controller 110. The process chamber 100 generally includes a top 124, a side 101 and a bottom wall 122 that define an interior volume 126. A support pedestal 150 is provided in the interior volume 126 of the chamber 100. The pedestal 150 may be fabricated from aluminum, ceramic, and other suitable materials. In one embodiment, the pedestal 150 is fabricated by a ceramic material, such as aluminum nitride, which is a material suitable for use in a high temperature environment, such as a plasma process environment, without causing thermal damage to the pedestal 150. The pedestal 150 may be moved in a vertical direction inside the chamber 100 using a lift mechanism (not shown).

The pedestal 150 may include an embedded heater element 170 suitable for controlling the temperature of a substrate 190 supported on the pedestal 150. In one embodiment, the pedestal 150 may be resistively heated by applying an electric current from a power supply 106 to the heater element 170. In one embodiment, the heater element 170 may be made of a nickel-chromium wire encapsulated in a nickel-iron-chromium alloy (e.g., INCOLOY®) sheath tube. The electric current supplied from the power supply 106 is regulated by the controller 110 to control the heat generated by the heater element 170, thereby maintaining the substrate 190 and the pedestal 150 at a substantially constant temperature during film deposition. The supplied electric current may be adjusted to selectively control the temperature of the pedestal 150 between about 100 degrees Celsius to about 780 degrees Celsius, such as greater than 500 degrees Celsius.

A temperature sensor 172, such as a thermocouple, may be embedded in the support pedestal 150 to monitor the temperature of the pedestal 150 in a conventional manner. The measured temperature is used by the controller 110 to control the power supplied to the heating element 170 to maintain the substrate at a desired temperature.

A vacuum pump 102 is coupled to a port formed in the walls of the chamber 100. The vacuum pump 102 is used to maintain a desired gas pressure in the process chamber 100. The vacuum pump 102 also evacuates post-processing gases and by-products of the process from the chamber 100.

A showerhead 120 having a plurality of apertures 128 is coupled to the top 124 of the process chamber 100 above the substrate support pedestal 150. The apertures 128 of the showerhead 120 are utilized to introduce process gases into the chamber 100. The apertures 128 may have different sizes, number, distributions, shape, design, and diameters to facilitate the flow of the various process gases for different process requirements. The showerhead 120 is connected to the gas panel 130 that allows various gases to supply to the interior volume 126 during process. A plasma is formed from the process gas mixture exiting the showerhead 120 to enhance thermal decomposition of the process gases resulting in the deposition of material on a surface 191 of the substrate 190.

The showerhead 120 and substrate support pedestal 150 may be formed a pair of spaced apart electrodes in the interior volume 126. One or more RF sources 140 provide a bias potential through a matching network 138 to the showerhead 120 to facilitate generation of a plasma between the showerhead 120 and the pedestal 150. Alternatively, the RF power sources 140 and matching network 138 may be coupled to the showerhead 120, substrate pedestal 150, or coupled to both the showerhead 120 and the substrate pedestal 150, or coupled to an antenna (not shown) disposed exterior to the chamber 100. In one embodiment, the RF sources 140 may provide between about 500 Watts and about 3000 Watts at a frequency of about 30 kHz to about 13.6 MHz.

The controller 110 includes a central processing unit (CPU) 112, a memory 116, and a support circuit 114 utilized to control the process sequence and regulate the gas flows from the gas panel 130. The CPU 112 may be of any form of a general purpose computer processor that may be used in an industrial setting. The software routines can be stored in the memory 116, such as random access memory, read only memory, floppy, or hard disk drive, or other form of digital storage. The support circuit 114 is conventionally coupled to the CPU 112 and may include cache, clock circuits, input/output systems, power supplies, and the like. Bi-directional communications between the control unit 110 and the various components of the processing system 132 are handled through numerous signal cables collectively referred to as signal buses 118, some of which are illustrated in FIG. 1.

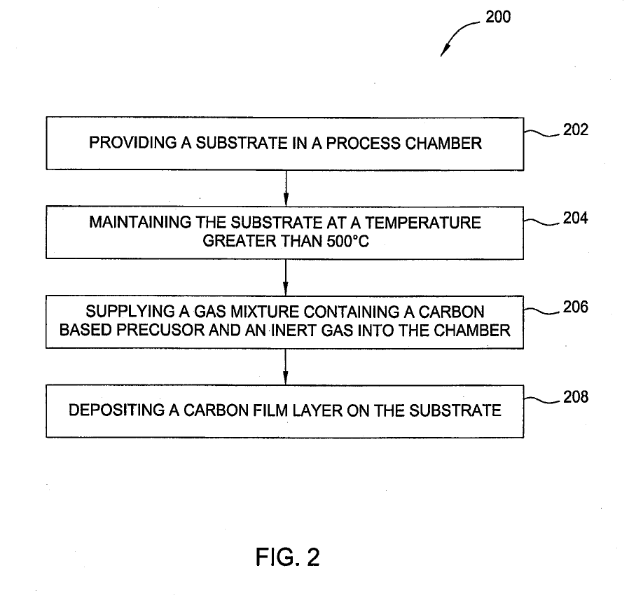

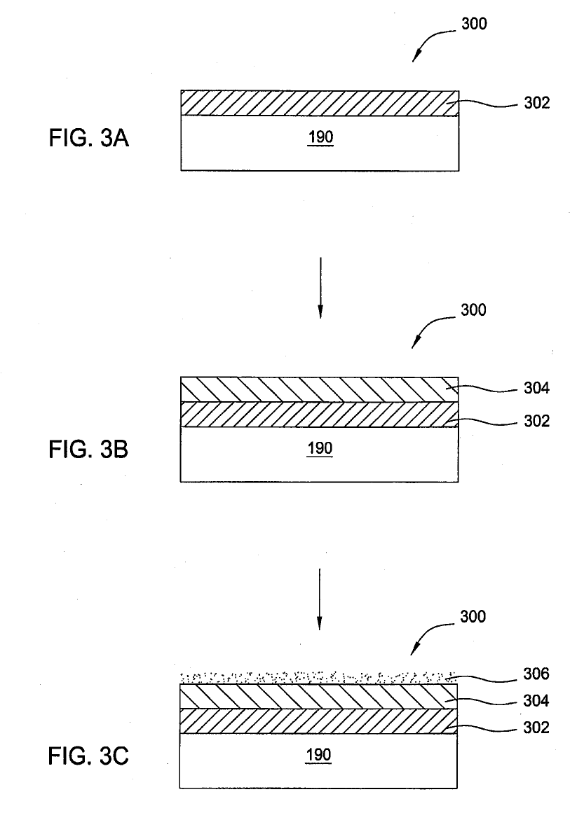

FIG. 2 illustrates a process flow diagram of a method 200 for depositing an amorphous carbon film according to one embodiment of the present invention. FIGS. 3A-3C is schematic cross-sectional view illustrating a sequence for depositing an amorphous carbon film for use as a hardmask layer deposited according to the method 200.

The method 200 begins at step 202 by providing a substrate in a process chamber. The process chamber may be the process chamber 100 as described in FIG. 1. It is contemplated that other process chambers, including those available from other manufacturers, may be utilized. The substrate 190, as shown in FIG. 3A, may have a material layer 302 disposed thereon. The substrate 190 may have a substantially planar surface, an uneven surface, or a substantially planar surface having a structure formed thereon. In one embodiment, the material layer 302 may be a part of a film stack utilized to form a gate structure, a contact structure, or shadow trench isolation (STI) structure. In embodiments wherein the material layer 302 is not present, the structures may be directly formed in the substrate 190.

In one embodiment, the material layer 302 maybe a silicon layer utilized to form a gate electrode. In another embodiment, the material layer 302 may include a silicon oxide layer, a silicon oxide layer deposited over a silicon layer. In yet another embodiment, the material layer 302 may include one or more layers of other dielectric materials utilized to fabricate semiconductor devices. In still another embodiment, the material layer 302 does not include any metal layers.

At step 204, the substrate is maintained at a temperature greater than about 500 degrees Celsius, such as between about 500 degrees Celsius and about 750 degrees Celsius. The substrate is maintained at a temperature higher than conventional deposition processes to control the reaction behavior of the decomposition of the gas mixture. Conventional deposition processes are typically performed lower than about 450 degrees Celsius. Conventional understanding is that the use of substrate temperatures greater than 450 degrees Celsius will result in lower deposition rate and poor film uniformity across the surface of the substrate, thereby resulting lower production throughput and less desirable film properties. Additionally, overly high process temperature would likely damage most conventional support pedestal used for this type of process, thereby reducing the lifespan of the pedestal and potentially increasing particle generation that contributes to process contamination. However, it is discovered that by using a carefully chosen substrate temperature greater than 500 degrees Celsius in conjunction with a carefully chosen gas mixture, which will be further described below, a processing window was discovered which enables a film with advantageous film properties and selectivity while maintaining a desired film deposition rate and within substrate film uniformity.

At step 206, a gas mixture is flowed from the gas panel 130 into the process chamber 100 through the showerhead 120. The gas mixture includes at least a hydrocarbon compound and an inert gas. In one embodiment, hydrocarbon compound has a formula CₓH_{y}, where x has a range between 1 and 12 and y has a range of between 4 and 26. More specifically, aliphatic hydrocarbons include, for example, alkanes such as methane, ethane, propane, butane, pentane, hexane, heptane, octane, nonane, decane and the like; alkenes such as propene, ethylene, propylene, butylene, pentene, and the like; dienes such as hexadiene butadiene, isoprene, pentadiene and the like; alkynes such as acetylene, vinylacetylene and the like. Alicyclic hydrocarbons include, for example, cyclopropane, cyclobutane, cyclopentane, cyclopentadiene, toluene and the like. Aromatic hydrocarbons include, for example, benzene, styrene, toluene, xylene, pyridine, ethylbenzene, acetophenone, methyl benzoate, phenyl acetate, phenol, cresol, furan, and the like. Additionally, alpha-terpinene, cymene, 1,1,3,3,-tetramethylbutylbenzene, t-butylether, t-butylethylene, methyl-methacrylate, and t-butylfurfurylether may be utilized. Additionally, alpha-terpinene, cymene, 1,1,3,3,-tetramethylbutylbenzene, t-butylether, t-butylethylene, methyl-methacrylate, and t-butylfurfurylether may be selected. In an exemplary embodiment, the hydrocarbon compounds are propene, acetylene, ethylene, propylene, butylenes, toluene, alpha-terpinene. In a particular embodiment, the hydrocarbon compound is propene (C₃H₆) or acetylene.

Alternatively, one or more hydrocarbon compounds may be mixed with the hydrocarbon compound in the gas mixture supplied to the process chamber. A mixture of two or more hydrocarbon compounds may be used to deposit the amorphous carbon material.

The inert gas, such as argon (Ar) or helium (He), is supplied with the gas mixture into the process chamber 100. Other carrier gases, such as nitrogen (N₂) and nitric oxide (NO), hydrogen (H₂), ammonia (NH₃), a mixture of hydrogen (H₂) and nitrogen (N₂), or combinations thereof may also be used to control the density and deposition rate of the amorphous carbon layer. The addition of H₂ and/or NH₃ may be used to control the hydrogen ratio (e.g., carbon to hydrogen ratio) of the deposited amorphous carbon layer. The hydrogen ratio present in the amorphous carbon film provides control over layer properties, such as reflectivity.

In one embodiment, an inert gas, such as argon (Ar) or helium (He) gas, is supplied with the hydrocarbon compound, such as propene (C₃H₆) or acetylene, into the process chamber to deposit the amorphous carbon film. The inert gas provided in the gas mixture may assist control of the optical and mechanical properties of the as-deposited layer, such as the index of refraction (n) and the absorption coefficient (k), hardness, density and elastic modulus of the formed layer. For example, during plasma depositing, the hydrocarbon compound supplied in the gas mixture may dissociate as carbon ions and hydrogen ions. Hydrogen ratio present in the deposited film may influence optical and mechanical properties. The atoms provided in the plasma dissociated the gas mixture, such as Ar or He atoms, generate certain amount of momentum in the gas mixture, thereby increasing the likelihood of plasma bombardment and, thus, driving out the hydrogen atom from film bonding formation. Accordingly, the ions contained in the gas mixture for film formation become mostly carbon ions, thereby increasing the likelihood of carbon and carbon double bond formation, resulting in higher absorption coefficient (k), e.g., lower transparency, and higher hardness, density and elastic modulus of the formed layer. Additionally, higher deposition temperature may also increase the likelihood of carbon and carbon double bond formation, thereby providing another alternative manner to adjust the optical and mechanical properties of the deposited film. As such, by controlling the hydrogen ratio contained in the formed deposited film, the optical and mechanical properties of the deposit film may be efficiently controlled and adjusted.

At step 208, an amorphous carbon film 304 is deposited on the material layer 302 and/or on the substrate 190 in the present of RF plasma with the substrate temperature controlled greater than 500 degrees Celsius, as shown in FIG. 3B. As discussed above, the hydrocarbon compound in the gas mixture decomposes at a relatively high temperature, allowing the bonding between the carbon and hydrogen atoms from the hydrocarbon compound being extensively decomposed and pyrolysis. Accordingly, the substantially decomposed carbon and hydrogen atoms may be reorganized and rearranged by the plasma generated from the gas mixture, thereby uniformly and gradually absorbing on the substrate surface and forming the amorphous carbon film 304 on the substrate 190. Disordered or disoriented atoms absorbed on the substrate surface often results in poor film structure and intrinsic film stress. Intrinsic film stress results in film voids, cracks, bowing, and hillocks which may significantly impact the feature transfer during the lithographic process, resulting in patterned line bending or line breakage during the subsequent etching process. Additionally, the intrinsic film stress of the formed amorphous carbon film may also result in stress mismatch between the adjacent layers formed on the substrate 190, thereby resulting in film crack or film structure bending and deformation. By elevating the substrate temperature at a range greater than 500 degrees Celsius in the presence of the right combination of process gases during the deposition process, the carbons and hydrogen atoms from the hydrocarbon compound may be substantially decomposed and reconstructed, thereby rearranging the order and lattices of the carbon atoms of the amorphous carbon film 304, producing a substantially flat surface with low stress film. As such, the carbon atoms may be deposited on the substrate surface in a more systematical and uniform manner.

In one embodiment, the stress of the deposited amorphous carbon film 304 is desired to be close to zero, e.g., a substantially flat surface of a non-compressive or non-tensile film. In excess of the overly-high process temperature and overly-high RF power used during the deposition process may result in the deposited carbon film overly tensilized or compressed which contributes to line-bending, stress mismatch, and/or film crack during the subsequent etching and depositing process. The desired film stress formed in the carbon film is between about 100 mega-pascal (MPa) tensile and about 100 mega-pascal (MPa) compressive. By carefully selecting the right amount of an inert gas for a given substrate process temperature, an amorphous carbon film having a film stress in this desired stress range may be obtained. The process window provided by the this combination of substrate process temperature and inert gas flow rate, also produces a desired combination of stress, mechanical and optical film properties. For example, too high an inert gas flow rate will make deposited film too compressive while no or too low of an inert gas flow rate will result in poor film uniformity and undesired n/k value. Higher temperature generally contributes to lower film stress, and as such, the inert gas rate may be reduced in response to the substrate temperature utilized to balance the process and achieve a close to zero stress in the deposited film.

Additionally, by adding the inert gas into the gas mixture, the hydrogen atoms dissociated by the plasma may be efficiently driven and compelled out from the gas mixture, as discussed above, thereby enhancing the carbon and carbon bonding in the deposited amorphous carbon film. The enhanced carbon and carbon bonding provides desired stronger mechanical properties, such as hardness, elastic modulus and density, thereby providing the deposition amorphous carbon film 304 having high resistance to plasma attack and high selectivity during the subsequent etching process. Furthermore, the optical properties, such as a desired range of index of refraction (n) and the absorption coefficient (k), of the formed carbon film 304 may be obtained by adjusting the amount of the inert gas supplied in the gas mixture while maintaining the film stress and etching selectivity at a desired range. Alternatively, different optical and mechanical properties of the deposited carbon film may also be obtained by selecting different hydrocarbon compounds, such as having different numbers and/or ratios of the carbon to hydrogen atoms, to meet different process requirements.

In one embodiment, the absorption coefficient (k) of the deposited amorphous carbon film may be controlled at between about 0.2 and about 1.8at a wavelength about 633 nm, and between about 0.4 and about 1.3 at a wavelength about 243 nm, and between about 0.3 and about 0.6 at a wavelength about 193 nm.

In one embodiment, the absorption coefficient of the amorphous carbon film 304 may also be varied as a function of the deposition temperature. In particular, as the temperature increases, the absorption coefficient (k) of the deposited layer likewise increases. Accordingly, a well selected combination of process temperature and the ratio of inert gas to hydrocarbon compound supplied in the gas mixture may be utilized to adjust the deposited carbon film with the desired range of stress and index of refraction (n) and the absorption coefficient (k).

In one embodiment, wherein the process temperature is controlled greater than about 500 degrees Celsius, such as between about 550 degrees Celsius and about 750 degrees Celsius, the hydrocarbon compound, such as propene (C₃H₆), may be supplied in the gas mixture at a rate between about 200 sccm and about 3000 sccm, such as between about 400 sccm and about 2000 sccm. The inert gas, such as Ar gas, may be supplied in the gas mixture at a rate between about 200 sccm and about 10000 sccm, such as about 1200 scom and about 8000 sccm.

During deposition, the process parameters may be regulated as needed. In one embodiment suitable for processing a 300 mm substrate, a RF source power of between about 400 Watts to about 2000 Watts, such as 800 Watts to about 1600 Watts, or a power density between 1.35 Watt/cm₂ and about 2.35 Watt/cm₂, may be applied to maintain a plasma formed from the gas mixture. The process pressure may be maintained at about 1 Torr to about 20 Torr, such as about 2 Torr and about 12 Torr, for example, about 4 Torr to about 9 Torr. The spacing between the substrate and showerhead may be controlled at about 200 mils to about 1000 mils. Details of other examples of process parameters for depositing the amorphous carbon film that may be used to practice the invention are described in commonly assigned U.S. Patent Publication No. 2005/0287771 published on Dec. 29, 2005, to Seamons et. al., and U.S. patent application Ser. No. 11/427,324 filed on Jun. 28, 2006, to Padhi et. al., (Attorney Docket No. 10847) and are herein incorporated by references.

The method 200 is particularly useful for the process used in the frond end process (FEOL) prior to metallization process in a semiconductor device manufacture process. Suitable frond end process (FEOL) includes gate manufacture applications, contact structure applications, shadow trench isolation (STI) process, and the like.

In the embodiments wherein the amorphous carbon film 304 is used as an etch stop layer or used as different films for different process purposes, the mechanical or optical properties of the film may be adjusted as well to meet the particular process purposes. For example, in the embodiment wherein the amorphous carbon film 304 is used as an etch stop layer, the mechanical properties of the film for providing a high selectivity to prevent over-etching the underlying layers may weight more than its optical properties, or vise versa.

In a particular embodiment wherein the amorphous carbon film 304 is used as a hardmask layer, after the amorphous carbon film 304 is deposited on the substrate 190, an optional capping layer 306 (shown in phantom in FIG. 3C) may be deposited on the amorphous carbon film 304. The optional capping layer 306 along with the amorphous carbon film 304 may serve as an anti-reflective coating (ARC) to facilitate the performance of the lithographic process when a resist layer is deposited on the capping layer 306. Suitable materials of the optional capping layer 306 include silicon, silicon oxide, silicon carbide (SiC), silicon oxynitride (SiON), silicon nitride (SiN) and other similar materials. The amorphous carbon film 304 may be used at Deep UV (DUV) lithography, Extreme Ultraviolet (EUV) lithography, immersion lithography, or other suitable lithographic technologies.

Thus, a method for depositing an amorphous carbon film having both desired mechanical and optical film properties are provided by using a high temperature deposition process. The method advantageously improves the mechanical properties, such as stress, hardness, elastic modulus, and density of the amorphous carbon film. The improved mechanical properties of the carbon film provides high film selectivity for the subsequent etching process while maintaining desired range of the film optical properties, such as index of refraction (n) and the absorption coefficient (k), for the subsequent lithography process.

While the foregoing is directed to embodiments of the present invention, other and further embodiments of the invention may be devised without departing from the basic scope thereof, and the scope thereof is determined by the claims that follow.

What is claimed is:

1. A method of depositing an amorphous carbon film, comprising:
providing a substrate in a process chamber;
heating the substrate to a temperature greater than 500 degrees Celsius;
supplying a gas mixture comprising a hydrocarbon compound and an inert gas into the process chamber containing the heated substrate; and
depositing an amorphous carbon film on the heated substrate having a stress of between 100 mega-pascal (MPa) tensile and about 100 mega-pascal (MPa) compressive.

2. The method of claim 1, wherein the hydrocarbon compound comprises at least one of methane, ethane, propane, butane, pentane, hexane, heptane, octane, nonane, decane, propene, ethylene, propylene, butylene, pentene, hexadiene, butadiene, isoprene, pentadiene, acetylene, vinylacetylene, cyclopropane, cyclobutane, cyclopentane, cyclopentadiene, toluene, benzene, styrene, toluene, xylene, pyridine, ethylbenzene, acetophenone, methyl benzoate, phenyl acetate, phenol, cresol, furan, alpha-terpinene, cymene, 1,1,3,3,-tetramethylbutylbenzene, t-butylether, t-butylethylene, methyl-methacrylate, t-butylfurfurylether, alpha-terpinene, cymene, 1,1,3,3,-tetramethylbutylbenzene, t-butylether, t-butylethylene, methyl-methacrylate, and t-butylfurfurylether.

3. The method of claim 1, wherein the hydrocarbon compound is at least one of propene or acetylene.

4. The method of claim 1, wherein the step of heating the substrate further comprises:
maintaining the substrate temperature between about 550 degrees Celsius and about 750 degrees Celsius.

5. The method of claim 1, wherein the step of providing the gas mixture into the process chamber further comprises:
flowing the hydrocarbon compound at a flow rate between about 200 sccm and about 3000 sccm; and
flowing the inert gas at a flow rate between about 200 sccm and about 10000 sccm.

6. The method of claim 1, wherein the inert gas is at least one of Ar or He.

7. The method of claim 1, wherein the step of depositing the amorphous carbon film further comprises:
selecting rate of inert gas provided to the process chamber in response to the substrate temperature.

8. The method of claim 1, wherein the step of depositing the amorphous carbon film further comprises:
applying a RF source power at between 400 Watts and 2000 Watts to energize the gas mixture.

9. A method of depositing an amorphous carbon film, comprising:
providing a substrate having a film stack in a process chamber, wherein the film stack has no metal layers contained therein;
flowing a gas mixture comprising a hydrocarbon compound and an inert gas into the process chamber, the inert gas selected from at least one of helium or argon gas;
maintaining the substrate at a temperature between about 550 degrees Celsius and about 750 degrees Celsius; and
depositing an amorphous carbon film on the heated substrate, wherein a rate of inert gas flow is selected commensurate with the substrate temperature to produce a stress of between 100 mega-pascal (MPa) tensile and about 100 mega-pascal (MPa) compressive in the deposited film.

10. The method of claim 9, wherein the hydrocarbon compound is at least one of propane or acetylene.

11. The method of claim 9, wherein the step of flowing the gas mixture into the process chamber further comprises:
flowing the hydrocarbon compound at a flow rate between about 200 sccm and about 3000 sccm; and
flowing the inert gas at a flow rate between about 200 sccm and about 10000 sccm.

12. The method of claim 11, wherein the step of depositing the amorphous carbon film further comprises:
applying a RF source power at between 400 Watts and 2000 Watts to energize the gas mixture.

13. The method of claim 9, wherein the step of depositing an amorphous carbon film on the substrate further comprising:
maintaining a process pressure at a range between about 2 Torr and about 10 Torr.

14. The method of claim 9, wherein the film stack is suitable to form a gate structure, a contact structure, or a shadow trench isolation structure.

15. A method of depositing an amorphous carbon film, comprising:
providing a substrate having a film stack in a process chamber, wherein the film stack has no metal layers contained therein;
flowing a gas mixture into the process chamber, the gas mixture comprising an inert gas and at least one of a propane compound or an acetylene compound, the inert gas selected from at least one of helium or argon gas;
maintaining the substrate at a temperature between about 550 degrees Celsius and about 750 degrees Celsius; and
depositing an amorphous carbon film on the substrate, wherein the amount of inert gas and the substrate temperature are selected to produce a predefined stress level between about 100 mega-pascal (MPa) tensile and about 100 mega-pascal (MPa) compressive in the deposited amorphous carbon film.

16. The method of claim 15, wherein the step of flowing the gas mixture further comprises:
flowing the propane or acetylene compound at a flow rate between about 200 sccm and about 3000 sccm; and
flowing the inert gas at a flow rate between about 200 sccm and about 10000 sccm.

17. The method of claim 15, wherein the step of maintaining the substrate temperature further comprises:
maintaining the substrate temperature between about 650 degrees Celsius and about 750 degrees Celsius

18. The method of claim 15, wherein the film stack is suitable to form a gate structure, a contact structure, or a shadow trench isolation structure.
